(19) United States
(12) Patent Application Publication
(10) Pub. No.: US 2026/0058100 A1
(43) Pub. Date: Feb. 26, 2026

(54) RF POWER AMPLIFIER UNIT FOR COUPLING RF SIGNALS FOR A PLASMA PROCESS SUPPLY SYSTEM AND A PLASMA PROCESS SYSTEM

(71) Applicant: TRUMPF HÜTTINGER GMBH + CO. KG, Freiburg (DE)

(72) Inventors: Florian MAIER, Pfaffenweiler (DE); Roland LODHOLZ, Ebringen (DE); Christian WANGLER, March (DE)

(21) Appl. No.: 19/378,397

(22) Filed: Nov. 4, 2025

Related U.S. Application Data
(63) Continuation of application No. PCT/EP2024/062337, filed on May 3, 2024.

(30) Foreign Application Priority Data
May 5, 2023 (DE) 10 2023 111 824.2

(51) Int. Cl. H01J 37/32; H03F 1/08; H03F 3/60

(52) U.S. Cl. CPC H01J 37/32183; H01J 37/32165; H03F 1/08; H03F 3/60; H01J 2237/24564; H03F 2200/255; H03F 2200/451; H03F 2200/543

(57) ABSTRACT

An RF power amplifier unit for coupling RF signals for a plasma process supply system and a plasma process system, the RF power amplifier unit being configured for powers≥2 kW and frequencies in a range from 10 MHz to 50 MHz, including a first RF power amplifier stage arrangement having a first output impedance positioned on a first heat sink section and a second RF power amplifier stage arrangement having a second output impedance positioned on a second heat sink section. The RF power amplifier unit further includes a first transmission line arrangement connected to an output of the first RF power amplifier stage arrangement and configured to transmit an output power of the first RF power amplifier stage arrangement and configured for a first line impedance equal to the output impedance of the first RF power amplifier stage arrangement.

### CROSS REFERENCE TO RELATED APPLICATIONS

This application is a continuation of International Application No. PCT/EP2024/062337 (WO 2024/231308 A1), filed on May 3, 2024, and claims benefit to German Patent Application No. DE 10 2023 111 824.2, filed on May 5, 2023. The aforementioned applications are hereby incorporated by reference herein.

### FIELD

The present invention relates to an RF power amplifier unit for coupling RF signals, to a plasma process supply system, a plasma process system, and to a method for supplying a load.

### BACKGROUND

A plasma process supply system is configured to supply a plasma process arrangement. A plasma process arrangement is an arrangement in which a plasma is generated and maintained in order to start and maintain a process. This may relate to a gas laser excitation arrangement. In particular, it may relate to a plasma processing arrangement. With such a plasma processing arrangement, materials and in particular their surfaces can be processed, for example, coated, etched or activated. Such plasma process arrangements are used, for example, in the manufacture of architectural glass, photovoltaic modules, displays, semiconductor components such as microcontrollers or semiconductor memory chips, etc. Since these are high-precision processes, the requirements for such plasma process arrangements and consequently also for the plasma process supply systems that supply them with electrical power are extremely high in terms of measurement and control accuracy, reliability, continuous operation, efficiency, etc. Such a plasma process supply system is often designed for power≥2 kW, preferably ≥4 kW and frequencies in the range of 2 MHz to 200 MHz, in particular in the range of 10 MHz to 50 MHz. Such a plasma process supply system often has one or a plurality of high-frequency signal sources, which are designed to jointly provide this required power and regulate it according to the process specifications. In addition, a plasma process supply system often has one or a plurality of impedance matching circuits, which are designed to match the impedance at the output of the high-frequency signal source(s) to the impedance at the input of the plasma process.

The output power of high-frequency signal sources, in particular of RF power amplifier stages with transistor amplifiers, is limited by the currently available transistors to a few 100 W up to a few kW. To achieve higher output power, a plurality of high-frequency signal sources must therefore be connected together. The combining can be implemented in RF power amplifier units.

The RF power amplifier units are intended to exhibit minimal losses over a wide bandwidth. In particular, high-frequency signal sources for plasma process supply systems require such RF power amplifier units. As the requirements for measurement and control accuracy as well as stability of plasma process supply systems are constantly increasing, the corresponding requirements for the RF power amplifier units used therein also continue to grow. At high power levels, RF power amplifier units often require a lot of space. In addition, the problem of interference effects due to unwanted emissions is increased.

A power combiner for such processes is known, for example, from DE 20 2016 008 958 U1.

The disadvantage of such a power combiner is that it is only suitable for a limited power output. This is because the number of high-frequency signal sources that can be positioned around it is limited by space.

### SUMMARY

In an embodiment, the present disclosure provides an RF power amplifier unit for coupling RF signals for a plasma process supply system and a plasma process system, the RF power amplifier unit being configured for powers≥2 kW and frequencies in a range from 10 MHz to 50 MHz, comprising a first RF power amplifier stage arrangement having a first output impedance positioned on a first heat sink section and a second RF power amplifier stage arrangement having a second output impedance positioned on a second heat sink section. The RF power amplifier unit further comprises a first transmission line arrangement connected to an output of the first RF power amplifier stage arrangement and configured to transmit an output power of the first RF power amplifier stage arrangement and configured for a first line impedance equal to the output impedance of the first RF power amplifier stage arrangement. The RF power amplifier unit further comprises a second transmission line arrangement connected to an output of the second RF power amplifier stage arrangement and configured to transmit an output power of the second RF power amplifier stage arrangement and configured for a second line impedance equal to the output impedance of the second RF power amplifier stage arrangement. The RF power amplifier unit further comprises a coupling line arrangement configured to transmit a sum of the output powers of the first and second RF power amplifier stage arrangements and configured for a coupling line impedance, the coupling line impedance being dependent on the first and second line impedances. The first and second transmission line arrangements are each connected to the coupling line arrangement in order to be able to transmit the output powers of the first and second RF power amplifier stage arrangements to the coupling line arrangement. The RF power amplifier unit further comprises a measuring device configured to determine a variable that describes the power output by the RF power amplifier stage arrangements and/or the RF power amplifier unit, the measuring device being positioned on at least one of the first transmission line arrangement, the second transmission line arrangement, and/or the coupling line arrangement.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 illustrates a schematic view of an embodiment of an RF power amplifier stage unit according to the present disclosure;

FIG. 2 illustrates a schematic view of an embodiment of an RF power amplifier unit according to the present disclosure;

FIG. 3 illustrates a schematic diagram of an embodiment of an RF power amplifier unit according to the present disclosure;

FIG. 4 illustrates an embodiment of an RF power amplifier unit according to the present disclosure; and

FIG. 5 illustrates a plasma process system with an RF power amplifier stage unit according to the present disclosure.

### DETAILED DESCRIPTION

In an embodiment, the present disclosure provides an RF power amplifier unit, which reliably combines a plurality of RF power amplifier stages in limited space and at high power levels and monitors the output power using a measuring device.

According to the present disclosure, an RF power amplifier unit for coupling RF signals, designed for powers≥2 kW, preferably ≥4 KW and frequencies in the range from 2 MHz to 200 MHz, in particular in the range from 10 MHz to 50 MHz, is provided, comprising:
a) a first RF power amplifier stage arrangement having a first output impedance positioned on a first heat sink section,
b) a second RF power amplifier stage arrangement having a second output impedance positioned on a second heat sink section,
c) a first transmission line arrangement connected to the output of the first RF power amplifier stage arrangement and designed to transmit the output power of the first RF power amplifier stage arrangement and designed for a first line impedance equal to the output impedance of the first RF power amplifier stage arrangement,
d) a second transmission line arrangement connected to the output of the second RF power amplifier stage arrangement and designed to transmit the output power of the second RF power amplifier stage arrangement and designed for a second line impedance equal to the output impedance of the second RF power amplifier stage arrangement,
e) a coupling line arrangement designed to transmit the sum of the output powers of the first and the second and the further RF power amplifier stage arrangements and designed for a coupling line impedance, wherein the coupling line impedance is dependent on the first, the second and the further line impedance, wherein
f) the first and second transmission line arrangements are each connected to the coupling line arrangement in order to be able to transmit the output powers of the first and second RF power amplifier stage arrangements to the coupling line arrangement,
g) a measuring device designed to determine a variable that describes the power output by the RF power amplifier stage arrangements and/or the RF power amplifier unit, said measuring device being positioned on at least one of the transmission and/or coupling line arrangements.

An RF power amplifier stage arrangement refers to an arrangement that can include a plurality of RF power amplifier stages, coupling elements and energy absorbers.

An energy absorber can be a component that is suitable for extracting electrical energy from the power combiner and converting it into heat, for example, like a resistor. However, this component can be designed to convert at least part of the energy in order to make this portion available again at another location.

A coupling element can be, for example, an inductance or a coupling line with a predetermined length, e.g., λ/4. If the plurality of coupling elements are all inductors, for example, they can advantageously always have the same inductance value, in particular they can be of identical construction. The plurality of coupling elements can be positioned in such a way that they scarcely, in particular not at all, influence each other. ‘Scarcely’ means such a small influence that it is negligible according to the laws of physics.

A heat sink section refers to a part of a cooling unit. The cooling unit can be designed at least in part as a cooling plate. The cooling unit can be composed of a plurality of parts made of different materials. Examples of such a cooling unit are disclosed and described in detail in the following publications: WO 2019/072894 A1, WO 2013/068004 A1, WO 2014/207185 A1.

This provides an RF power amplifier unit that reliably combines the output powers of two RF power amplifier stage arrangements in a limited space and monitors the power of the RF power amplifier stage arrangement and/or the output power of the RF power amplifier unit using a measuring device. In addition, a shielding effect can be achieved by arranging the RF power amplifier stage arrangements on heat sink sections. This can prevent disruptive effects such as unwanted radiation.

The reason for this can also be that the RF power amplifier stages often cannot be positioned very close to each other because they
often generate so much heat that they have to be cooled by cooling units, and/or
carry such high currents and voltages, due to their high power generation, that they would negatively influence each other by emitting high-frequency fields.

One solution is to place the RF power amplifier stages further apart from each other and/or to shield them appropriately. In both cases, the outputs of the RF power amplifier stages can only be positioned at a distance from each other. They therefore have a distance that is disadvantageous for the power combiner. This disadvantage can be overcome by the advantageous combining with the previously described transmission line arrangements and the coupling line arrangement.

In an aspect of the RF power amplifier unit, the following relationship can apply for the coupling line impedance with respect to the first and second line impedances: ZC′=1/(1/Z1′+1/Z2′) with
ZC′: coupling line impedance,
Z1′: first line impedance and
Z2′: second line impedance.

In this way, interference caused by reflections can be further reduced and the measurement, and thus the control, can be further improved.

In an aspect of the RF power amplifier unit, the first and second line impedances can be equal.

In this way, interference caused by reflections can be further reduced and the measurement, and thus the control, can be further improved.

In an aspect of the RF power amplifier unit, the first and second line impedances can each be twice the coupling line impedance.

In this way, interference caused by reflections can be further reduced and the measurement, and thus the control, can be further improved.

In an aspect, the RF power amplifier unit can further comprise:
a) one, in particular a plurality of, further RF power amplifier stage arrangement(s), each having a further output impedance and each positioned on a further heat sink section, and
b) one, in particular a plurality of, further transmission line arrangement(s), each connected to the respective output of the further RF power amplifier stage arrangement(s) and each designed to transmit the output power of the further RF power amplifier stage arrangement(s) and each designed for a further line impedance equal to the output impedance of the further RF power amplifier stage arrangement(s), wherein
c) the coupling line arrangement is designed to transmit the sum of the output powers of the first and the second and the further RF power amplifier stage arrangements and designed for a coupling line impedance, wherein the coupling line impedance is dependent on the first, the second and the further line impedance, and wherein
d) the further transmission line arrangement(s) are each connected to the coupling line arrangement in order to be able to transmit the output power(s) of the further RF power amplifier stage arrangement to the coupling line arrangement.

In this way, the advantages of the present disclosure can be achieved even at higher power levels.

In an aspect of the RF power amplifier unit, the following relationship can apply for the coupling line impedance with respect to the first, the second and further line impedances:

$$\begin{matrix}ZC ‘ = 1 / ( 1 / Z 1 ‘ + 1 / Z 2 ‘ + 1 / Zn ‘ ) with \\ ZC ‘ : coupling line impedance , \\ Z 1 ‘ : first line impedance , \\ Z 2 ‘ : second line impedance and \\ Zn ‘ : further line impedances .\end{matrix}$$

Where nϵN. This means that n can be a natural number, so n=1, 2, 3, 4, . . . . The number n indicates the number of line impedances. For n=3 as an example, a third line impedance Z3′ results for the further line impedances Zn′ and the following applies: ZC′=1/Z1′1/Z2′+1/Z3′). For n=4 as an example, a third line impedance Z3′ and a fourth line impedance Z4′ result for the further line impedances Zn′, and the following applies: ZC′=1/(1/Z1′+1/Z2′+1/Z3′+1/Z4′). In this way, this can also be continued for larger numerical values of n.

The number of line impedances results from the number of transmission line arrangements of the RF power amplifier unit.

In this way, interference caused by reflections can be further reduced even at higher power levels, and the measurement, and thus the control, can be further improved.

In an aspect of the RF power amplifier unit, the further line impedance(s) can be equal to the first and/or second line impedance.

In this way, interference caused by reflections can be further reduced even at higher power levels, and the measurement, and thus the control, can be further improved.

In an aspect of the RF power amplifier unit, the further line impedance(s) can each be N times as large as the coupling line impedance wherein N=number of the first, second and n-th transmission line arrangements.

In this way, interference caused by reflections can be further reduced even at higher power levels, and the measurement, and thus the control, can be further improved.

In an aspect of the RF power amplifier unit, one, in particular a plurality of, particularly preferably all, transmission line arrangements can comprise:
a signal conductor designed to transmit the respective output signal of the RF power amplifier stage arrangements,
a reference conductor which is electrically connected to a potential which is invariable with respect to the reference ground, in particular with the reference ground.

In this way, interference caused by radiation can be further reduced and the measurement, and thus the control, can be further improved.

In an aspect of the RF power amplifier unit, the coupling line arrangement can comprise:
a coupling signal conductor designed to transmit the combined output signals of the RF power amplifier stage arrangements,
a coupling reference conductor which is electrically connected to a potential which is invariable with respect to the reference ground, in particular with the reference ground.

In this way, interference caused by radiation can be further reduced and the measurement, and thus the control, can be further improved.

In an aspect of the RF power amplifier unit, one, in particular a plurality of, particularly preferably all, transmission line arrangements can be designed as a microstrip line.

In this way, interference caused by radiation can be further reduced and the measurement, and thus the control, can be further improved.

In an aspect of the RF power amplifier unit, one, in particular a plurality of, particularly preferably all, transmission line arrangements can be designed as a coaxial line.

In this way, interference caused by radiation can be further reduced and the measurement, and thus the control, can be further improved.

In an aspect of the RF power amplifier unit, the coupling line arrangement can be designed as a microstrip line.

In this way, interference caused by radiation can be further reduced and the measurement, and thus the control, can be further improved.

In an aspect of the RF power amplifier unit, the coupling line arrangement can be designed as a coaxial line.

In this way, interference caused by radiation can be further reduced and the measurement, and thus the control, can be further improved.

In an aspect of the RF power amplifier unit, one, in particular a plurality of, particularly preferably all, transmission line arrangements can be connected, at their connection, in particular at their signal connection, to the respective RF power amplifier stage arrangement(s) by means of a pin, which can in particular be part of the respective transmission line arrangements.

This makes production easier and allows for very reliable and production-accurate measurements.

In an aspect of the RF power amplifier unit, one, in particular a plurality of, particularly preferably all, RF power amplifier stage arrangement(s) can be positioned on printed circuit boards, which in turn are positioned on the respective heat sink sections and in particular the transmission line arrangements are connected to electrical contacts of these printed circuit boards.

In this way, interference caused by radiation can be further reduced and the measurement, and thus the control, can be further improved.

In an aspect of the RF power amplifier unit, the heat sink sections can each be positioned on a separate cooling unit.

In this way, interference caused by radiation can be further reduced and the measurement, and thus the control, can be further improved.

In an aspect of the RF power amplifier unit, the heat sink sections can be positioned so that they enclose a space surrounded by them.

In this way, interference caused by radiation can be further reduced and the measurement, and thus the control, can be further improved.

In an aspect of the RF power amplifier unit, the coupling line arrangement can be positioned within a space enclosed by the heat sink sections.

In this way, interference caused by radiation can be further reduced and the measurement, and thus the control, can be further improved.

In an aspect of the RF power amplifier unit, one, in particular a plurality of, particularly preferably all, transmission line arrangement(s) can be positioned, for the most part, within a space enclosed by the heat sink sections.

In this way, interference caused by radiation can be further reduced and the measurement, and thus the control, can be further improved.

In an aspect of the RF power amplifier unit, the measuring device can be positioned within a space enclosed by the heat sink section.

In this way, interference caused by radiation can be further reduced and the measurement, and thus the control, can be further improved.

In an aspect of the RF power amplifier unit, one, in particular a plurality of, particularly preferably all, RF power amplifier stage arrangement(s) can be positioned outside a space enclosed by the heat sink sections.

In this way, interference caused by radiation can be further reduced and the measurement, and thus the control, can be further improved.

In an aspect of the RF power amplifier unit, a plurality of, particularly preferably all, RF power amplifier stage arrangement(s) can be constructed identically and, in particular, can be positioned line-symmetrically to the coupling line arrangement.

This improves the reliability of the RF power amplifier unit because identical parts can be used.

In an aspect of the RF power amplifier unit, the cooling unit(s) can be designed, in particular embodied, as fluid-cooled cooling unit(s), in particular cooling plate(s), for example for cooling with air, a liquid or a combination of both.

This can improve the reliability of the RF power amplifier unit because the RF power amplifier unit does not heat up as much and temperature-sensitive components remain operational for longer.

In an aspect of the RF power amplifier unit, one, in particular a plurality of, particularly preferably all, RF power amplifier stage arrangement(s) can have a plurality of amplifier stages whose outputs are connected to the inputs of a power combiner part which comprises:
a plurality of inputs and one output,
a plurality of coupling elements, in particular inductors, each connecting the inputs to the output of the power combiner part,
an energy absorber, in particular a resistor, which connects the inputs of the power combiner part, in particular a plurality of energy absorbers, in particular resistors, which connect the inputs of the power combiner part, in particular in a star shape.

In this way, interference caused by reflections can be further reduced even at higher power levels, and the measurement, and thus the control, can be further improved.

In an aspect of the RF power amplifier unit, the RF power amplifier unit can comprise a power combiner, comprising:
a plurality of power combiner parts,
a plurality of further transmission line arrangement(s), each connected to an output of the power combiner parts,
a coupling line arrangement and
in particular a balancing line.

In this way, interference caused by reflections can be further reduced even at higher power levels, and the measurement, and thus the control, can be further improved.

A balancing line can be a line with a fixed characteristic impedance and a length of n*λ/2 wherein nϵN.

Such a balancing line is described, for example, in DE 10 2023 111 812.9, filed on May 5, 2023, which is incorporated in its entirety by reference into this application.

Such a balancing line can be used to avoid cross-feeding of the RF power amplifier stages used as high-frequency signal sources and uneven distribution of reflected output power. If the amplitudes, phases or internal impedances of the RF power amplifier stages connected to the power combiner are unequal, a push-pull signal is generated that is harmful to the high-frequency signal sources. Additionally or alternatively, if the reflected power is distributed unequally, the phases and/or amplitude as well as the load impedance of the individual RF power amplifier stages can change. This can lead to excessive stress on the most heavily loaded RF power amplifier stage.

To avoid this, the balancing line can be connected to the inputs of a power combiner.

The balancing line can also be designed as a balancing circuit with additional elements such as resistors.

In particular, the specified characteristic impedance of the balancing line can be equal to the characteristic impedance at the corresponding input.

The specified characteristic impedance of the balancing line can in particular be equal to an integer multiple of the characteristic impedance at the corresponding input.

The specified characteristic impedance of the balancing line can in particular be equal to an integer fraction of the characteristic impedance at the corresponding input.

The specified characteristic impedance of the balancing line can in particular be equal to 25Ω, 50Ω2 or 100Ω.

λ generally refers to the wavelength of the radio frequency signals within the corresponding line, i.e., here within the balancing line, at a frequency within the operating frequency range, in particular the center frequency of the operating frequency range.

nϵ [symbol] means that n can be a natural number, i.e., n=1, 2, 3, 4, . . . .

An ‘operating frequency range’ refers to a frequency range within which the power combiner and the RF power amplifier stages that can be connected thereto are operated, i.e., for which they are designed. This can be a very narrowband operating frequency range, for example 13.54 MHz-13.58 MHz, or a somewhat broader band, for example 13.06 MHz to 14.06 MHz. In both cases, the center frequency would be 13.56 MHz. An operating frequency range is usually specified by the manufacturer of a power combiner as the nominal frequency range. This will vary depending on the application area of the power combiner. If a power combiner is part of an RF power amplifier unit, it is also designed for at least this operating frequency range.

Advantages of the present disclosure are also achieved by a plasma process supply system comprising at least one RF power amplifier unit as described above and an impedance matching circuit connected downstream thereof. For example, a power combiner as described above can be used particularly advantageously and ensure particular reliability and stability of the system.

Advantages of the present disclosure are also achieved by a plasma process system comprising a plasma process supply system as described above and a plasma process arrangement which is connected to the impedance matching circuit.

For example, a power combiner as described above can be used particularly advantageously and ensure particular reliability and stability of the system.

Advantages of the present disclosure are also achieved by a method for supplying a load, in particular a plasma process arrangement, with a power amplifier unit as described above, and in particular with an impedance matching circuit connected downstream thereof, which in turn is particularly preferably connected to a plasma process arrangement, wherein
a) a first output power is generated by a first RF power amplifier stage arrangement,
b) a second first output power is generated by a second RF power amplifier stage arrangement,
c) the first output power from a first transmission line arrangement and
d) a second output power from a second transmission line arrangement
e) are transmitted to a coupling line arrangement,
f) which transmits the coupled-together output powers of the first and second RF power amplifier stage arrangements to an output of the power amplifier unit, and
a) a measuring device is used to determine a quantity that describes the power output by the RF power amplifier stage arrangements and/or the RF power amplifier unit at one of the transmission and/or coupling line arrangements, and
g) the load is supplied with these coupled-together output powers.

The task can be solved particularly advantageously in this way.

Preferred exemplary embodiments of the present dislcosure are shown schematically in the drawings and are explained in more detail below with reference to the figures of the drawing.

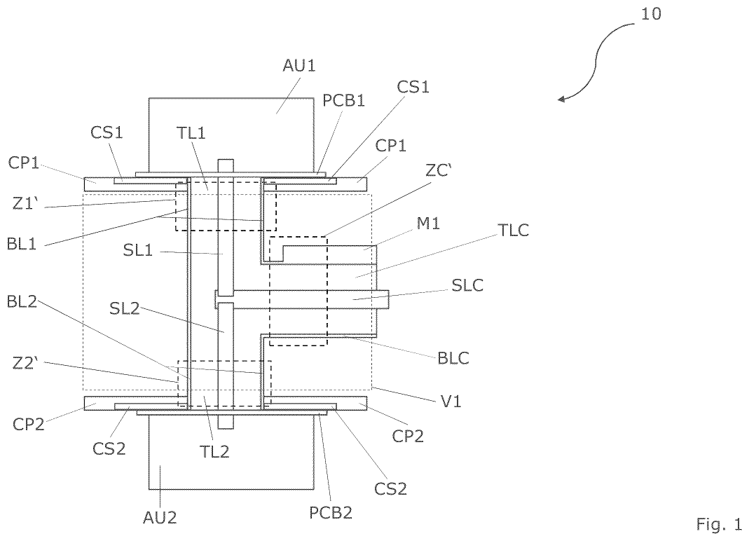

FIG. 1 shows a first embodiment of an RF power amplifier unit 10 according to the present disclosure. The RF power amplifier unit 10 comprises two RF power amplifier stage arrangements AU1, AU2, two cooling units CP1, CP2, two heat sink sections CS1, CS2, two printed circuit boards PCB1, PCB2, two transmission line arrangements TL1, TL2, a measuring device M1 and a coupling line arrangement TLC. The first RF power amplifier stage arrangement AU1 is positioned on the first printed circuit board PCB1. Via this first printed circuit board PCB1, the first RF power amplifier stage arrangement AU1 is also positioned on the first heat sink section CS1. The first heat sink section CSI is part of the first cooling unit CP1. The second RF power amplifier stage arrangement AU2 is positioned on the second printed circuit board PCB2. Via this second circuit board PCB2, the second RF power amplifier stage arrangement AU2 is also positioned on the second heat sink section CS2. The second heat sink section CS2 is part of the second cooling unit CP1.

The two cooling units CP1, CP2 are positioned in such a way that they enclose a space V1.

The first transmission line arrangement TL1 connects the first RF power amplifier stage arrangement AU1 to the coupling line arrangement TLC and has a first signal conductor SL1 and a first reference conductor BL1. The second transmission line arrangement TL2 connects the second RF power amplifier stage arrangement AU2 to the coupling line arrangement TLC and has a second signal conductor SL2 and a second reference conductor BL2. The coupling line arrangement TLC has a coupling signal conductor SLC and a coupling reference conductor BLC.

The two signal conductors SL1, SL2 are designed to transmit the respective output signal of the RF power amplifier stage arrangements AU1, AU2. The two reference conductors BL1, BL2 represent the reference potential to the two signal conductors SL1, SL2 and are electrically connected to a potential that is unchanging with respect to the reference ground. This potential can also be the reference ground itself.

The two transmission line arrangements TL1, TL2 are brought together and connected to the coupling line arrangement TLC. The coupling signal line SLC is designed to transmit the combined output signals of the two RF power amplifier stage arrangements AU1, AU2. The coupling reference conductor BLC represents the reference potential of the coupling signal conductor SLC and is electrically connected to a potential that is constant with respect to the reference ground. This potential can also be the reference ground itself. The measuring device M1 is integrated into the coupling line arrangement TLC and is designed to determine the combined power of the two RF power amplifier stage arrangements AU1, AU2.

The measuring device M1 can, for example, comprise at least one directional coupler or a current sensor and a voltage sensor. Via the at least one directional coupler, the measuring device M1 can measure the power of the RF signal which is transmitted from the RF power supply unit 10 towards the impedance matching circuit 11 or the load. Preferably, the measuring device M1 can also measure the power of an RF signal which is reflected at the impedance matching circuit 11 back towards the RF power supply unit 10. The power of the RF signal transmitted from the RF power supply unit 10 towards the impedance matching circuit 11 can also be determined via the current sensor and the voltage sensor. A power of an RF signal reflected by the impedance matching circuit 11 can also be detected by the current sensor and the voltage sensor.

A typical measuring device M1 is shown, for example, in one of the following publications: WO2019/185424 A1, WO2013/143537 A1, US2009/0140722 A1, US2006/0232265 A1, DE 20 2011 051 371 U1.

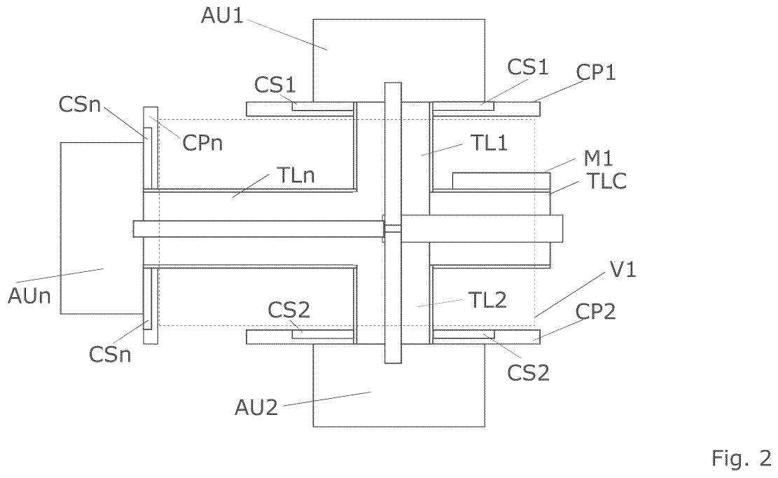

FIG. 2 shows a further embodiment of an RF power amplifier unit 10 according to the present disclosure. The RF power amplifier unit 10 is constructed very similarly to the RF power amplifier unit 10 in FIG. 1. However, it has an additional third RF power amplifier stage arrangement AUn. This third RF power amplifier stage arrangement AUn is positioned on a third heat sink section CSn. The third heat sink section CSn is part of a third cooling unit C3. The third RF power amplifier arrangement AUn is combined with the first and second RF power amplifier arrangements AU1, AU2 via a third transmission line arrangement TLn and connected to the coupling power arrangement TLC. The third transmission line arrangement TLn has the same structure as the two transmission line arrangements TL1, TL2 from FIG. 1. In contrast to the embodiment in FIG. 1, the RF power amplifier unit in this embodiment does not have any printed circuit boards. The RF power amplifier stage arrangements AU1, AU2, AUn are positioned directly on the cooling units CP1, CP2, CPn. In addition, the first cooling unit CP1 has a first heat sink section CS1.

More detailed descriptions of the individual components, which are also mentioned in FIG. 1, can be found in the description of FIG. 1.

Overall, the RF power amplifier unit 10 in this embodiment is designed to combine the output signals of the three RF power amplifier stage arrangements AU1, AU2, AUn and to further transmit the combined power via the coupling power arrangement TLC.

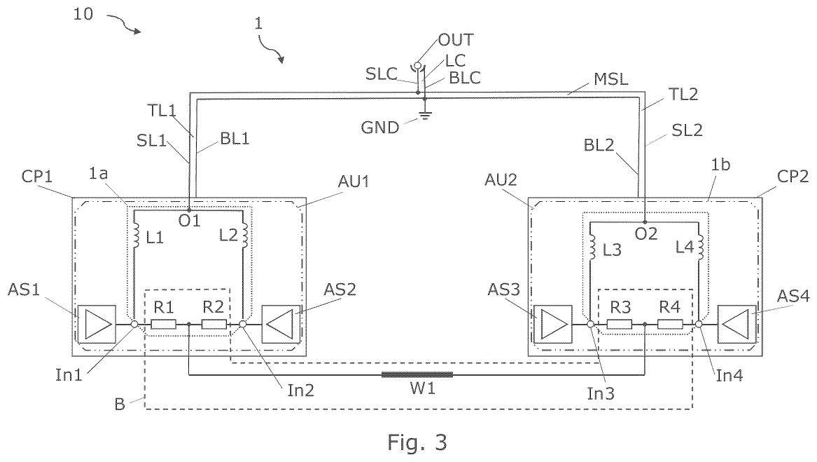

FIG. 3 shows a further embodiment of a power amplifier unit 10 according to the present disclosure. The power amplifier unit 10 comprises a power combiner 1, four RF power amplifier stages AS1-AS4 and two cooling units CP1, CP2. The power combiner 1 comprises four inputs In1-In4, a main output OUT, four coupling elements designed as inductors L1-L4 and a balancing circuit B. The RF power amplifier stages AS1-AS4 are connected to the inputs In1- In4. The inductors L1-L4 connect the inputs In1-In4 to the main output OUT.

The first two inputs In1, In2 are connected to a first output O1 via the first two inductors L1, L2, and the second two inputs In3, In4 are connected to a second output 02 via the second two inductors L3, L4. The two outputs 01, 02 are then connected to the main output OUT.

The four inductors L1-L4 and the four RF power amplifier stages AS1-AS4 are positioned on the two cooling units CP1, CP2. On the first cooling unit CP1 are the first two inductors L1, L2 and the first two RF power amplifier stages AS1, AS2. The RF power amplifier stages AS1, AS2 and the components of a first power combiner part 1a, namely the coupling elements designed here as inductors L1, L2 and the energy absorbers designed here as resistors R1, R2, together form a first RF power amplifier stage arrangement AU1. The second two inductors L3, L4 and the second two RF power amplifier stages AS3, AS4 are positioned on the second cooling unit CP2. The RF power amplifier stages AS3, AS4 and the components of a second power combiner part 1b, namely the coupling elements designed here as inductors L3, L4 and the energy absorbers designed here as resistors R3, R4, together form a second RF power amplifier stage arrangement AU2.

The balancing circuit B has four energy absorbers designed as resistors R1-R4 and a balancing line W1 of length n*λ/2. The balancing circuit B connects the four inputs In1-In4. For this purpose, the first two inputs In1, In2 are connected to each other via the first two resistors R1, R2, positioned on the first cooling unit CP1. The first resistor R1 is connected to the first input In1 and the second resistor R2 is connected to the second input In2. Likewise, the second two inputs In3, In4 are connected to each other via the second two resistors R3, R4, positioned on the second cooling unit CP2. The third resistor R3 is connected to the third input In3 and the fourth resistor R4 is connected to the fourth input In4. The balancing line W1 then connects all four inputs In1-In4 with each other.

In this way, two, in particular more than two RF power amplifier stage arrangements AU1, AU2 can be connected to each other. If more than two RF power amplifier stage arrangements AU1, AU2 are connected together, a plurality of balancing lines can be connected in a star configuration.

Individual, in particular a plurality of, particularly preferably all, RF power amplifier stage arrangements AU1, AU2 can also have more than two RF power amplifier stages AS1, AS2. Accordingly, these can then also have more than two components of the power combiner parts 1a, 1b, i.e., more than two coupling elements designed here as inductors L1, L2 and more than two energy absorbers designed here as resistors R1, R2.

FIG. 3 also shows a possible connection arrangement of the two outputs O1, O2 of the two RF power amplifier stage arrangements AU1, AU2 with the main output OUT.

The first output O1 of the first RF power amplifier stage arrangement AU1 is connected to a first transmission line arrangement TL1. The first transmission line arrangement TL1 has a first signal conductor SL1 and a first reference conductor BL1. The second output O2 of the second RF power amplifier stage arrangement AU2 is connected to a second transmission line arrangement TL2. The second transmission line arrangement TL2 has a second signal conductor SL2 and a second reference conductor BL2.

The two signal conductors SL1, SL2 are designed to transmit the respective output signal of the RF power amplifier stage arrangements AU1, AU2. The two reference conductors BL1, BL2 represent the reference potential to the two signal conductors SL1, SL2 and are electrically connected to a potential that is unchanging with respect to the reference ground. In this case, this potential is the reference ground GND itself.

The two transmission line arrangements TL1, TL2 are brought together and connected to a coupling line arrangement TLC. The coupling line arrangement TLC has a coupling signal line SLC and a coupling reference line BLC. The coupling signal line SLC is designed to transmit the combined output signals of the two RF power amplifier stage arrangements AU1, AU2. The coupling reference conductor BLC represents the reference potential of the coupling signal conductor SLC and is electrically connected to a potential that is constant with respect to the reference ground. In this case, this potential is the reference ground GND itself. The coupling line arrangement TLC is connected to the main output OUT of the power amplifier unit 10.

In this case, the two transmission line arrangements TL1, TL2 are designed as microstrip lines MSL.

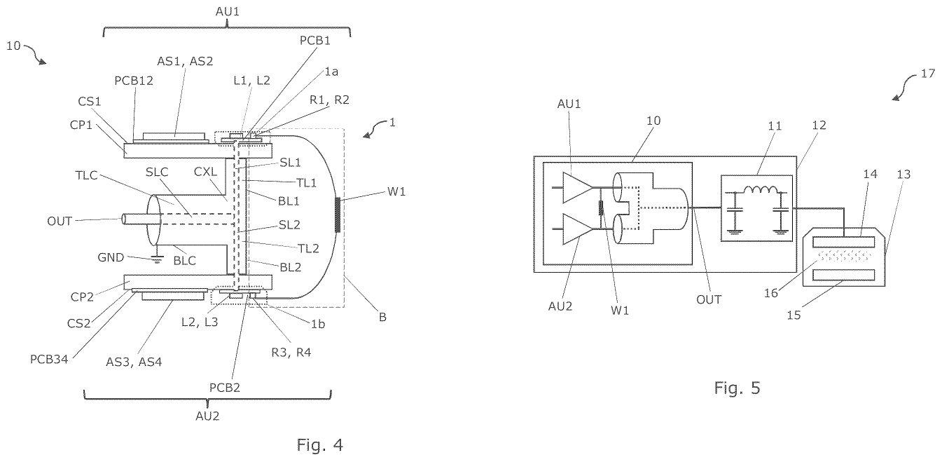

FIG. 4 shows an embodiment of a power amplifier unit 10 according to the present disclosure. The power amplifier unit 10 is very similar to the power amplifier unit 10 in FIG. 3, only shown in a different view, and the connection arrangement of the two outputs O1, O2 of the two RF power amplifier stage arrangements AU1, AU2 with the main output OUT is designed as a coaxial line CXL. The descriptions of the two transmission line arrangements TL1, TL2, the two signal conductors SL1, SL2, the two reference conductors BL1, BL2, the coupling line arrangement TLC, the coupling signal line SLC and the coupling reference conductor BLC can be found in the description of FIG. 3.

The two cooling units CP1, CP2 can each have a heat sink section CS1, CS2. It is also provided that a plurality of heat sink sections CS1, CS2 are positioned on a common cooling plate, but spaced apart from each other. For example, the first heat sink section CSI can be positioned on a first side of a cooling unit and the second heat sink section CS2 can be positioned on the back of the same cooling unit.

In contrast to the power amplifier unit 10 in FIG. 3, the power amplifier unit 10 here has two combiner circuit boards PCB1, PCB2.

The first combiner circuit board PCB1 is positioned on the first heat sink section CS1 and thus, in this embodiment, also on the first cooling unit CP1. The second combiner circuit board PCB2 is positioned on the second heat sink section CS2 and thus, in this embodiment, also on the second cooling unit CP2. Furthermore, the power amplifier unit 10 has the power combiner 1 from FIG. 3. Shown are the four RF power amplifier stages AS1-AS4, each distributed into the RF power amplifier stage arrangements AU1, AU2. Also shown are the four coupling elements designed as inductors L1-L4, the main output OUT and the balancing circuit B. The balancing circuit B comprises the four energy absorbers designed as resistors R1-R4 and the balancing line W1 of length n*λ/2.

The first two RF power amplifier stages AS1, AS2 are positioned on a first amplifier circuit board PCB12. The first two RF power amplifier stages AS1, AS2 are positioned with this first amplifier circuit board PCB12 on the first heat sink section CS1 and thus, in this embodiment, also on the first cooling unit CP1. The second two RF power amplifier stages AS3-AS4 are positioned on a second amplifier circuit board PCB34. The second two RF power amplifier stages AS3-AS4 are positioned with this second amplifier circuit board PCB12 on the second heat sink section CS2 and thus, in this embodiment, also on the second cooling unit CP2.

The first combiner circuit board PCB1 can also be combined with the first amplifier circuit board PCB12 to form a common circuit board.

The second combiner circuit board PCB2 can also be combined with the second amplifier circuit board PCB34 to form a common circuit board.

This simplifies manufacturing and reduces the number of cable connections between circuit boards, making the overall system more reliable.

The first two inductors L1, L2 and the first two resistors R1, R2 are positioned on the first combiner circuit board PCB1. The second two inductors L3, L4 and the second two resistors R3, R4 are positioned on the second combiner circuit board PCB2.

FIG. 5 shows a plasma process system 17 having a plasma process supply system 12.

The plasma process supply system 12 has a power amplifier unit 10 with a power combiner 1. These can be designed as described above.

The plasma process supply system 12 also comprises an impedance matching circuit 11.

The main output OUT of the power combiner 1 is connected to the input of the impedance matching circuit 11. The output terminal of the impedance matching circuit 11 is connected to the load, in this case a plasma processing arrangement in a plasma chamber 13.

The plasma chamber 13 comprises:
a substrate 15 that is processed, e.g., coated or etched, by the plasma 16,
an electrode 14 with which the RF power is coupled into the plasma chamber 13 in order to ignite and maintain the plasma 16.

The impedance matching circuit 11 is designed to transform the input impedance of the plasma process at its output to the output impedance of the power amplifier unit 10. Designs of such plasma process systems and/or impedance matching circuits are described, for example, in the following published applications: DE 10 2009 001 355 A1, DE 10 2011 007 597 A1, DE 10 2011 007 598 A1, WO 2021/209390 A1, WO 2021/255250 A1.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. An RF power amplifier unit for coupling RF signals for a plasma process supply system and a plasma process system, the RF power amplifier unit being configured for powers≥2 KW and frequencies in a range from 10 MHz to 50 MHz, comprising:
a first RF power amplifier stage arrangement having a first output impedance positioned on a first heat sink section;
a second RF power amplifier stage arrangement having a second output impedance positioned on a second heat sink section;
a first transmission line arrangement connected to an output of the first RF power amplifier stage arrangement and configured to transmit an output power of the first RF power amplifier stage arrangement and configured for a first line impedance equal to the output impedance of the first RF power amplifier stage arrangement;
a second transmission line arrangement connected to an output of the second RF power amplifier stage arrangement and configured to transmit an output power of the second RF power amplifier stage arrangement and configured for a second line impedance equal to the output impedance of the second RF power amplifier stage arrangement;
a coupling line arrangement configured to transmit a sum of the output powers of the first and second RF power amplifier stage arrangements and configured for a coupling line impedance, the coupling line impedance being dependent on the first and second line impedances,
the first and second transmission line arrangements being each connected to the coupling line arrangement in order to be able to transmit the output powers of the first and second RF power amplifier stage arrangements to the coupling line arrangement;
a measuring device configured to determine a variable that describes the power output by the RF power amplifier stage arrangements and/or the RF power amplifier unit, the measuring device being positioned on at least one of the first transmission line arrangement, the second transmission line arrangement, and/or the coupling line arrangement.

2. The RF power amplifier unit according to claim 1, wherein the coupling line impedance (ZC′) satisfies the following relationship with respect to the second and first line impedances (Z2′, Z1′):
$$ZC ‘ = {( Z 1 {‘}^{- 1} + Z 2 {‘}^{- 1} )}^{- 1} .$$
3 The RF power amplifier unit according to claim 1, wherein the second and first line impedances are equal.

4. The RF power amplifier unit according to claim 1, wherein the second and first line impedances are each twice as large as the coupling line impedance.

5. The RF power amplifier unit according to claim 1, wherein the RF power amplifier unit further comprises:
a plurality of further RF power amplifier stage arrangements each having a further output impedance and each positioned on a further heat sink section; and
a plurality of further transmission line arrangements, each connected to a respective output of the further RF power amplifier stage arrangements and each configured to transmit an output power of the further RF power amplifier stage arrangements and each configured for a further line impedance equal to the output impedance of the further RF power amplifier stage arrangements, wherein
the coupling line arrangement is configured to transmit a sum of the output powers of the first and the second and the further RF power amplifier stage arrangements and configured for a coupling line impedance, wherein the coupling line impedance is dependent on the first, the second and the further line impedance, and wherein
the further transmission line arrangements are each connected to the coupling line arrangement in order to be able to transmit the output powers of the further RF power amplifier stage arrangement to the coupling line arrangement.

6. The RF power amplifier unit according to claim 5, wherein the coupling line impedance (ZC′) satisfies the following relationship with respect to the first, second and further line impedances (Zn′, Z2′, Z1′):
$$ZC ‘ = {( Z 1 {‘}^{- 1} + Z 2 {‘}^{- 1} + Zn {‘}^{- 1} )}^{- 1} .$$

7. The RF power amplifier unit according to claim 5, wherein the further line impedances are equal to the second and/or the first line impedance.

8. The RF power amplifier unit according to claim 5, wherein the further line impedances are each N times as large as the coupling line impedance with N=a number of first, second and n-th transmission line arrangements.

9. The RF power amplifier unit according to claim 5, wherein a plurality of the transmission line arrangements comprise:
a signal conductor configured to transmit a respective output signal of the first, second, and further RF power amplifier stage arrangements, and
a reference conductor which is electrically connected to a potential which is invariable with respect to a reference ground.

10. The RF power amplifier unit according to claim 9, wherein the coupling line arrangement comprises:
a coupling signal conductor configured to transmit combined output signals of the first, second, and further RF power amplifier stage arrangements, and
a coupling reference conductor which is electrically connected to a potential which is invariable with respect to the reference ground.

11. The RF power amplifier unit according to claim 5, wherein a plurality of the first, second and further transmission line arrangements are configured as a microstrip line.

12. The RF power amplifier unit according to claim 5, wherein a plurality of the first, second, and further transmission line arrangements are configured as a coaxial line.

13. The RF power amplifier unit according to claim 1, wherein the coupling line arrangement is configured as a microstrip line.

14. The RF power amplifier unit according to claim 1, wherein the coupling line arrangement is configured as a coaxial line.

15. The RF power amplifier unit according to claim 5, wherein a plurality of the first, second, and further transmission line arrangements are connected with their signal connection to a respective RF power amplifier stage arrangement of the first, second, and further RF power amplifier stage arrangements by a pin that is part of a respective transmission line arrangement of the first, second, and further transmission line arrangements.

16. The RF power amplifier unit according to claim 1, wherein a plurality of the first, second, and further RF power amplifier stage arrangements are positioned on printed circuit boards, which in turn are positioned on respective heat sink sections of the first, second, and further heat sink sections and wherein the transmission line arrangements are connected to electrical contacts of the printed circuit boards.

17. The RF power amplifier unit according to claim 5, wherein the first, second, and further heat sink sections are each positioned on a separate cooling unit.

18. The RF power amplifier unit according to claim 5, wherein the first, second, and further heat sink sections are positioned such that they surround a space enclosed by the first, second, and further heat sink sections.

19. The RF power amplifier unit according to claim 5, wherein the coupling line arrangement is positioned within a space which is surrounded by the first, second, and further heat sink sections.

20. The RF power amplifier unit according to claim 1, wherein a plurality of the first, second and further transmission line arrangements are positioned within a space surrounded by the first, second, and further heat sink sections.

21. The RF power amplifier unit according to claim 5, wherein the measuring device is positioned within a space that is surrounded by the first, second, and further heat sink sections.

22. The RF power amplifier unit according to claim 5, wherein a plurality of the first, second, and further RF power amplifier stage arrangements are positioned outside a space that is surrounded by the first, second, and further heat sink sections.

23. The RF power amplifier unit according to claim 5, wherein a plurality of the first, second, and further RF power amplifier stage arrangements are constructed identically and are positioned line-symmetrically with respect to the coupling line arrangement.

24. The RF power amplifier unit according to claim 17, wherein the cooling units are embodied as fluid-cooled cooling plates.

25. The RF power amplifier unit according to claim 1, wherein a plurality of the first, second, and further RF power amplifier stage arrangements have a plurality of amplifier stages whose outputs are connected to inputs of a power combiner part which comprises:
a plurality of inputs and one output,
a plurality of inductors each connecting the inputs to the output of the power combiner part,
a resistor which connects the inputs of the power combiner part.

26. The RF power amplifier unit according to claim 1, comprising a power combiner, which comprises:
a plurality of power combiner parts,
a plurality of further transmission line arrangements each connected to an output of the power combiner parts,
a coupling line arrangement, and
a balancing line.

27. A plasma process supply system comprising at least one RF power amplifier unit according to claim 1, and an impedance matching circuit connected downstream thereof.

28. A plasma process system comprising the plasma process supply system according to claim 27 and a plasma process arrangement connected to the impedance matching circuit.

29. A method for supplying a load with the power amplifier unit according to claim 1, and with an impedance matching circuit connected downstream thereof, the method comprising:
generating a first output power by the first RF power amplifier stage arrangement;
generating a second first output power by the second RF power amplifier stage arrangement;
transmitting the first output power from the first transmission line arrangement and a second output power from the second transmission line arrangement to a coupling line arrangement;
transmitting the coupled-together output powers of the first and second RF power amplifier stage arrangements to an output of the power amplifier unit, and
using the measuring device to determine a quantity that describes the power output by the RF power amplifier stage arrangements and/or the RF power amplifier unit at one of the first transmission line arrangement, the second transmission line arrangement, and/or the coupling line arrangement; and
supplying the load with the coupled-together output powers.
